(19) United States
(12) Patent Application Publication
(10) Pub. No.: US 2015/0228694 A1
(43) Pub. Date: Aug. 13, 2015

(54) Monolithically integrated CMOS and acoustic wave device

(71) Applicant: The Silanna Group Pty, Ltd, Eight Mile Plains, Queeensland (AU)

(72) Inventor: Andrew John Brawley, Cecil Hills (AU)

(21) Appl. No.: 14/367,892

(22) PCT Filed: Dec. 4, 2012
(86) PCT No.: PCT/AU2012/001475

§ 371 Date: Jun. 20, 2014

Related U.S. Application Data
(60) Provisional application No. 61/578,219, filed on Dec. 20, 2011.

(51) Int. Cl. H01L 27/20; H01L 41/187; H01L 27/12; H01L 41/29; H01L 41/047; H01L 21/84; H01L 41/113

(52) U.S. Cl. CPC H01L 27/20; H01L 21/84; H01L 41/187; H01L 41/1132; H01L 41/29; H01L 41/0471; H01L 27/1203

(57) ABSTRACT

An integrated CMOS and acoustic wave device, including: an electrically insulating piezoelectric thin film having opposed first and second surfaces; one or more CMOS devices formed in a semiconductor thin film disposed on one or more portions of the first surface of the piezoelectric thin film; and at least one acoustic wave structure having electrically conductive transducer electrodes disposed on at least one of the first and second surfaces of the piezoelectric thin film.

### TECHNICAL FIELD

The present invention relates to monolithically integrated acoustic wave and CMOS devices, and processes for producing same.

### BACKGROUND

Acoustic wave devices such as surface acoustic wave (SAW) and thin film bulk acoustic resonator (FBAR) devices are important for many applications, including telecommunications and sensing. These applications generally require micro-scale or nano-scale machined acoustic wave structures to provide band-pass filters, dispersive delay lines, and oscillators, for example. In order to facilitate the use of such structures with CMOS electronics, there is a desire to produce, at relatively low cost, a single device that includes CMOS electronics and one or more acoustic wave structures/devices by integrating the corresponding manufacturing/process technologies. However, such integration is technologically challenging, and to date predominantly takes the form of hybrid integration or heterogeneous integration; for example, by flip-chip bonding one or more pre-made acoustic wave devices to a pre-made CMOS device. Although there have been reports of homogeneous or monolithic integration in the literature, these remain limited in scope, and generally involve forming acoustic wave structures and piezoelectric materials over the top of the metal layers of complete pre-existing CMOS devices.

It is desired to provide an integrated CMOS and acoustic wave device and a process for producing an integrated CMOS and acoustic wave device that alleviate one or more difficulties of the prior art, or that at least provide a useful alternative.

### SUMMARY

In accordance with the present invention, there is provided an integrated CMOS and acoustic wave device, including:
an electrically insulating piezoelectric thin film having opposed first and second surfaces;
one or more semiconductor-on-insulator (SOI) CMOS devices formed in a semiconductor thin film disposed on one or more portions of the first surface of the electrically insulating piezoelectric thin film; and
at least one acoustic wave structure having electrically conductive transducer electrodes disposed on at least one of the first and second surfaces of the piezoelectric thin film.

In some embodiments, the CMOS devices include at least one of partially depleted and fully depleted CMOS devices.

In some embodiments, the piezoelectric thin film provides a substantial cooling path for the CMOS devices. In some embodiments, the piezoelectric thin film is substantially unsupported and the majority of the cooling through the piezoelectric thin film is along the plane of the piezoelectric thin film.

In some embodiments, In some embodiments, the electrically conductive transducer electrodes are disposed on at least the second surface of the piezoelectric thin film. In some embodiments, the electrically conductive transducer electrodes are disposed on the first and second surfaces of the piezoelectric thin film.

In some embodiments, at least some of the electrically conductive transducer electrodes on the first surface of the piezoelectric thin film are aligned with corresponding ones of the electrically conductive transducer electrodes on the second surface of the piezoelectric thin film.

In some embodiments, the device includes electrically conductive contacts that pass through the piezoelectric thin film.

In some embodiments, the electrically conductive transducer electrodes define interdigitated acoustic wave transducers.

In some embodiments, the at least one acoustic wave structure includes at least one surface acoustic wave structure. In some embodiments, the at least one acoustic wave structure includes at least one bulk acoustic wave structure.

In some embodiments, the device includes a handle substrate bonded to the first side of the semiconductor thin film via one or more layers, the one or more layers including one or more interconnect layers.

In some embodiments, the semiconductor thin film is a silicon thin film and the piezoelectric thin film is an AlN thin film.

In accordance with the present invention, there is provided a process for producing an integrated CMOS and acoustic wave device, including:
forming or receiving a semiconductor-on-insulator (SOI) substrate having a semiconductor thin film disposed on an electrically insulating piezoelectric thin film disposed on a supporting substrate;
forming CMOS devices in one or more first portions of the semiconductor thin film; and
forming at least one acoustic wave structure having mutually spaced electrically conductive transducer electrodes disposed on at least one surface of the piezoelectric thin film, at least one dielectric material being disposed therebetween and on the at least one surface of the piezoelectric thin film.

In some embodiments, the piezoelectric thin film has opposed first and second surfaces, the semiconductor thin film is disposed on the first surface of the piezoelectric thin film, and the transducer electrodes are disposed on at least the second surface of the piezoelectric thin film. In some embodiments, the transducer electrodes are disposed on the first and second surfaces of the piezoelectric thin film.

In some embodiments, the process includes forming electrically conductive contacts that pass through the piezoelectric thin film to interconnect the transducer electrodes across the piezoelectric thin film.

In some embodiments, the CMOS devices include at least one of partially depleted and fully depleted CMOS devices.

In some embodiments, the piezoelectric thin film provides a substantial cooling path for the CMOS devices. In some embodiments, the process includes removing the supporting substrate to expose the piezoelectric thin film, wherein the majority of cooling through the piezoelectric thin film is along the plane of the piezoelectric thin film.

In some embodiments, the process includes:
forming one or more further layers over the CMOS devices, the one or more further layers including one or more interconnect layers;
bonding a handle superstrate to an outermost one of the one or more layers; and
removing the supporting substrate to expose the piezoelectric thin film.

In some embodiments, the process includes selectively removing one or more second portions of the semiconductor thin film to form the one or more first portions of the semiconductor thin film as mutually spaced semiconductor islands on the piezoelectric thin film.

In some embodiments, the semiconductor thin film is a silicon thin film and the piezoelectric thin film is an AlN thin film.

### BRIEF DESCRIPTION OF THE DRAWINGS

Some embodiments of the present invention are hereinafter described, by way of example only, with reference to the accompanying drawings, wherein:

FIG. 1 is a flow diagram of a process for producing a monolithically integrated CMOS and acoustic wave device;

FIG. 2 is a flow diagram of a first contact process of the process of FIG. 1;

FIG. 3 is a flow diagram of a second contact process of the process of FIG. 1;

FIG. 4 is a schematic cross-sectional side view of a semiconductor-on-insulator (SOI) wafer or substrate in which the buried insulating layer under the semiconductor thin film is an electrical insulator having piezoelectric properties suitable for the generation and transmission of acoustic waves;

FIGS. 5 to 14 each includes a schematic plan view and a corresponding cross-sectional side view of a portion of the (SOI) substrate of FIG. 4 at successive steps of the process of FIG. 1; and

FIGS. 15 and 16 each includes a schematic plan view and a corresponding cross-sectional side view of a portion of the final integrated SOI CMOS and acoustic wave structure/device produced by the process of FIGS. 1 to 3, where the acoustic wave structure is a bulk acoustic wave structure or a surface acoustic wave structure, respectively.

### DETAILED DESCRIPTION

Described herein are monolithically integrated CMOS (complementary metal-oxide-semiconductor) and acoustic wave devices and integrated processes for producing same, wherein CMOS devices are formed in a thin film semiconductor-on-insulator (SOI) structure. The SOI structure includes a semiconductor thin film disposed on a thin film insulator that is also piezoelectric and provides the acoustic wave medium for the acoustic wave structures/devices. Thus the acoustic wave structures include one or more first portions of the piezoelectric thin film, and one or more second portions of the piezoelectric thin film provide the insulator of the SOI substrate from which the CMOS devices are formed. The CMOS devices may include partially depleted and/or fully depleted CMOS devices.

The acoustic wave structures described herein include electrically conductive transducer electrodes disposed on at least one side of the piezoelectric thin film. That is, the piezoelectric thin film has opposed first and second planar surfaces or faces, and the transducer electrodes can be disposed on the first surface only, or on the second surface only, or on both surfaces of the piezoelectric thin film.

In the embodiments described in detail below, the semiconductor is silicon (Si) and the piezoelectric thin film is an aluminium nitride (AlN) thin film, which, despite being an electrical insulator, has a relatively high thermal conductivity and thus provides a substantial thermally conductive path for heat flow from the CMOS devices. This can be particularly important in embodiments wherein the AlN thin film below the CMOS devices is not supported below the CMOS devices; that is, there is no substrate or substantial underlying layer that would provide an efficient thermal path below the AlN thin film, which may be freestanding, or at best only covered on its underside by one or more thin layers that themselves do not provide a substantial thermal path to conduct heat from the CMOS devices. This requires the CMOS devices to be effectively cooled by lateral heat flow along the plane of the AlN thin film, rather than orthogonally through the film to a heat sink.

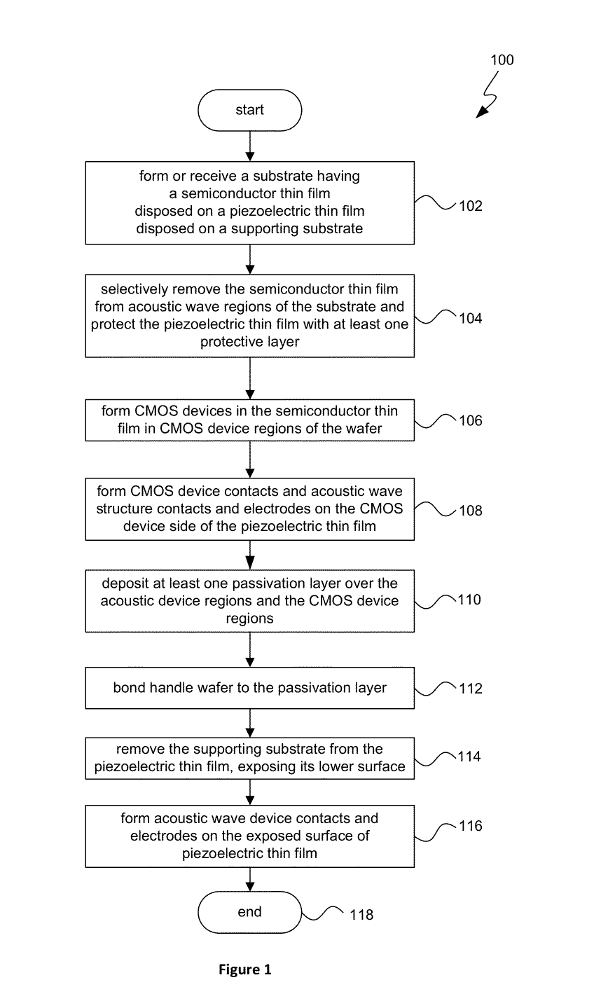

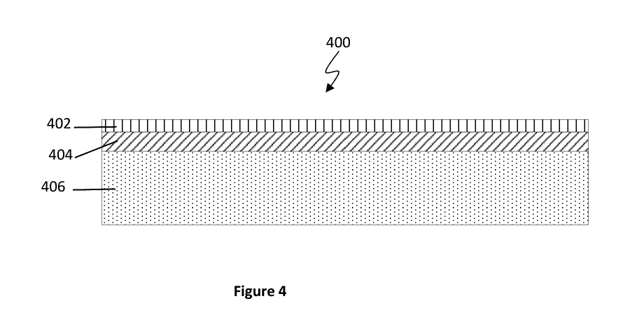

FIGS. 1 to 3 are flow diagrams of a process for producing a monolithically integrated CMOS and acoustic wave device. The process begins at step 102 by receiving or forming an SOI substrate or wafer 400, as shown in cross-sectional side view in FIG. 4, in which a semiconductor thin film 402 is disposed on an electrically insulating piezoelectric thin film 404, which in turn is disposed on a supporting substrate or wafer 406. In this specification and particularly in the claims, except where context indicates otherwise, the word “wafer” is used for convenience of reference, and should not be construed as being limited to its ordinary meaning of an entire disc-shaped substrate, but rather should be understood broadly as encompassing any shape or form of substrate or layer, including a complete wafer or a portion of a complete wafer.

In the described embodiments, the SOI substrate or wafer 400 includes a silicon thin film 402 disposed on an electrically insulating AlN thin film 404 disposed in turn on a supporting substrate 406, which may itself be a silicon substrate or wafer. The SOI substrate 400 may be of a type (and/or may be formed by a process as) described in U.S. Patent Application No. 61/556,121 and in International Patent Application No. PCT/AU2012/001348, both entitled “Method of Producing a Silicon-On-Insulator Article”, the entirety of which are hereby expressly incorporated herein by reference. However, it will be apparent to those skilled in the art that other forms and/or compositions of SOI substrate or wafer could alternatively be used in other embodiments, providing that the electrical insulator of the substrate or wafer is composed of a material that is also sufficiently piezoelectric to be used to form acoustic wave devices.

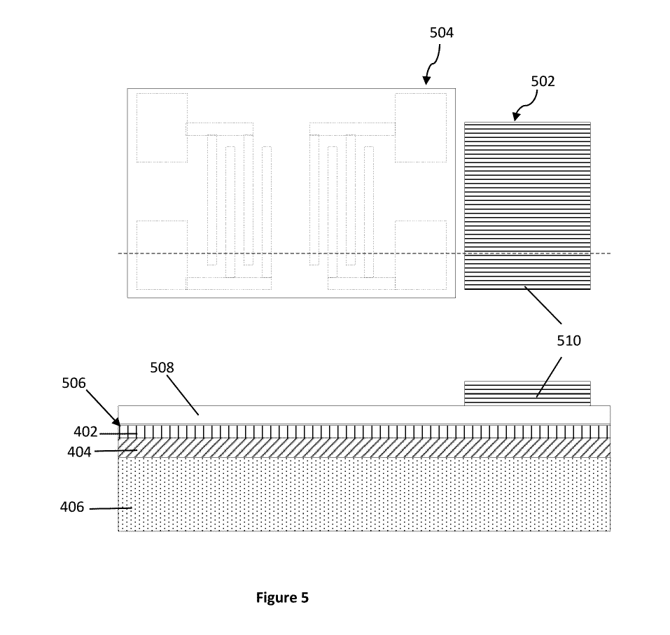

As shown schematically in the upper part of FIG. 5, the available area of the SOI wafer 400 in plan view can be considered as being divided up into different regions, including one or more CMOS device regions 502 and one or more acoustic wave device/structure regions 504, with one or more CMOS devices being formed in the CMOS device regions 502, and one or more surface acoustic wave (SAW) and/or bulk acoustic wave (BAW) devices/structures being formed in each of the acoustic wave device/structure regions 504.

In the embodiment described in detail below, the starting SOI substrate 400 consists of a thin, device-quality layer of (100) silicon 402 having a thickness of about 750 Å to 1100 Å disposed on a layer of aluminium nitride (AlN) 404 having a thickness of about 2000 Å, which in turn is disposed on a 150 mm diameter silicon substrate 406 having a thickness of about 675 μm. However, it will be understood by those skilled in the art that these values are exemplary only, and other values may be used in other embodiments.

At step 102, the silicon layer 402 is selectively removed from the acoustic wave device/structure regions 504, and the newly exposed piezoelectric thin film 404 is then protected by at least one protective layer, as follows. First, and as shown in the process flow of Table 1 below, a pad oxide 506 having a thickness of about 11 nm is grown over the entire SOI wafer. A 145 nm layer of silicon nitride (nominally Si₃N₄) 508 is then deposited on the pad oxide layer 506 and over the entire wafer. A layer of photoresist 510 is then deposited and patterned using standard optical lithography so that the remaining photoresist 510 protects the nitride layer 508 in the CMOS device regions 502, while the nitride layer 508 in the acoustic wave device/structure regions 504 is exposed, as shown in the lower part of FIG. 5. In this and the following Figures, the cross-sectional side view in the lower part of each Figure is taken along the horizontal dotted line shown in the plan view in the upper part of the Figure.

TABLE 1

| Step | Operation | Tool | Condition | Target | BAW | SAW |
|---|---|---|---|---|---|---|
| Substrate | Lot start | | Si/AlN/Si (NOsub)Substrate | 110 nm | Lot start | Lot start |
| Pad Oxide | Oxide Strip | | 50:1HF etch | | Oxide Strip | Oxide Strip |
| | Oxidation | Tylan Tytan AP | Dry SiO2 | 11 nm | Oxidation | Oxidation |
| Active Area | LP-Nitride Deposition | Tylan Tytan AP | Silicon nitride | 145 nm | LP-Nitride Deposition | LP-Nitride Deposition |
| | Active Photo | PAS5500/60 | | | SAW Active Area Photo | SAW Active Area Photo |

As shown in the process flow of Table 2 below, the exposed nitride layer 508 is then removed from the acoustic wave device/structure regions 504 by etching, and the photoresist mask 510 stripped, so that the nitride layer 508 remains only in the CMOS device regions 502.

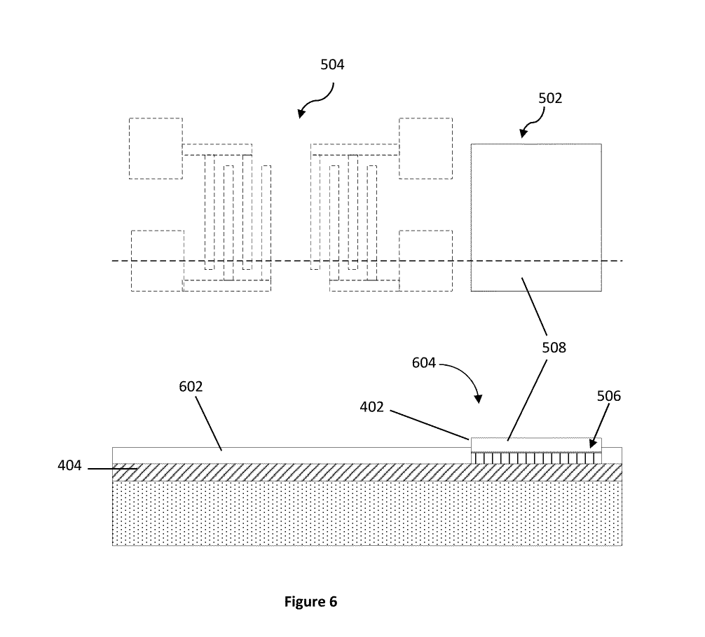

The exposed portions of the silicon layer 506 in the acoustic wave device regions 504 are then fully oxidised using a standard LOCOS process, and the resulting 220 nm SiO₂ layer is then partially etched back to a thickness of about 145 nm to provide a field oxide layer 602 that protects the underlying piezoelectric thin film 404 during the subsequent CMOS device formation process 106. Thus the silicon layer 402 remains only in the CMOS device regions 502. The resulting structure is shown in FIG. 6. Although only one region or “island” 604 of the silicon layer 402 is shown for clarity, typically there will be many such islands; in some embodiments, one for each MOS transistor.

TABLE 2

| Step | Operation | Tool | Condition | Target | BAW | SAW |
|---|---|---|---|---|---|---|
| Active Area | Active Etch | LAM TCP9406SE | | | Active Etch | Active Etch |
| | PR Strip | YES or Gasonics | Dry-SPM | | PR Strip | PR Strip |
| Field Oxide | Oxidation | Tylan Tytan AP | Wet SiO2 | 220 nm | Oxidation | Oxidation |
| | Field Ox Etch Back | | 7:1BOEtch | 145 nm | Field Ox Etch Back | Field Ox Etch Back |

### CMOS Device Formation

Now that the silicon layer 402 has been removed from the acoustic wave device/structure regions 504, and the piezoelectric thin film 404 in those regions that would otherwise be exposed is protected by the field oxide layer 602, CMOS devices are formed in the silicon islands 604 remaining in the CMOS device regions 502 at step 106.

Essentially any standard CMOS SOI process can be used to form the CMOS devices in the respective thin film silicon islands 604. Many such suitable processes will be known or otherwise available to those skilled in the art, and consequently need not be described here in any detail. In the described process 106, a standard CMOS SOI process is used to form the CMOS devices in the silicon islands 604 remaining in the CMOS device regions 502 of the SOI wafer 400, but only up to the steps used to form electrical contacts to the CMOS devices, or more specifically, up to a step of depositing an inter-layer dielectric (ILD) layer. While the CMOS devices are being formed, the piezoelectric thin film insulator 404 remains protected by at least one protective layer in the acoustic wave device/structure regions 504 of the substrate 400.

By definition, a CMOS device includes MOS transistors with both n-type and p-type channels. In the described embodiments, these devices are formed by masked ion implantation of the appropriate dopant species into corresponding regions of the silicon thin film islands 604 to dope the source, drain and channel regions of each MOS transistor. Tables 3, 4 and 5 summarise one possible CMOS SOI process flow up to the contact mask definition step. However, many other suitable processes will be apparent to those skilled in the art.

As shown in the process flow of Table 3 below, the CMOS SOI process flow begins by first stripping both the nitride mask 508 and the 11 nm pad oxide 506 from the silicon islands 604, and then growing a thin, approximately 11 nm sacrificial oxide layer on the newly exposed silicon islands 604.

TABLE 3

| Step | Operation | Tool | Condition | Target | BAW | SAW |
|---|---|---|---|---|---|---|
| | Nitride Strip | | 100:1HF-H3PO4 | | Nitride Strip | Nitride Strip |
| Sac Oxide | Oxide Strip | | 50:1HF etch | | Oxide Strip | Oxide Strip |
| | Oxidation | Tylan Tytan AP | Wet SiO2 | 11 nm | Oxidation | Oxidation |

As shown in the process steps of Table 4 below, the CMOS processing up to and including the P⁺ source and drain implant steps has the acoustic wave device regions masked and protected during these processing steps.

TABLE 4

| Step | Operation | Tool | Condition | Target | BAW | SAW |
|---|---|---|---|---|---|---|
| RN | RN Photo | PAS5500/60, PAS2500/40 | | | Masked | Masked |
| | RN Vₜ Implant | Varian EHPi500 | BF2 implant | | Masked | Masked |
| | PR Strip | YES or Gasonics | Dry-SPM | | PR Strip | PR Strip |
| RP | RP Photo | PAS5500/60, PAS2500/40 | | | Masked | Masked |
| | RP VₜImplant | Varian EHPi500 | P₃₁ implant | | Masked | Masked |
| | PR Strip | YES or Gasonics | Dry-SPM | | PR Strip | PR Strip |
| Gate Oxide | Oxide Strip | | SPM-50:1HF etch | | Oxide Strip | Oxide Strip |
| | Oxidation | SVG 8507 TOX AVP | Wet SiO2 | 82 Å | Oxidation | Oxidation |
| Poly | Poly Deposition | Tylan Tytan AP | | 250 nm | Poly Deposition | PolyDeposition |
| | N + Poly Photo | PAS5500/60, PAS2500/40 | N + mask | | Masked | Masked |
| | N + Poly Implant | Varian VIISion 80 | As implant | | Masked | Masked |
| | PR Strip | Gasonics | Dry-SPM | | PR Strip | PR Strip |
| | N + Poly Anneal | Tylan Tytan AP | N2 anneal | | N + Poly Anneal | N + Poly Anneal |
| | P + Poly Photo | PAS5500/60, PAS2500/40 | P + mask | | Masked | Masked |
| | P + Poly Implant | Varian VIISion 80 | BF2 implant | | Masked | Masked |
| | PR Strip | Gasonics | Dry-SPM | | PR Strip | PR Strip |
| | P + Poly Anneal | Tylan Tytan AP | N2 anneal | | P + Poly Anneal | P + Poly Anneal |
| CoSi | Cobalt Silicide | Varian | | 150 nm | Cobalt Silicide Sputter | Cobalt Silicide Sputter |
| | Sputter | | | | | |
| Cap Oxide | PECVD Ox | Novellus Concept1 | | 170 nm | PECVD Ox | PECVD Ox |
| Gate | Gate Photo | ASML5500/550 | | | Masked | Masked |
| | Barc/Ox Etch | LAM TCP9406SE | | | Barc/Ox Etch | Barc/Ox Etch |
| | CoSi/Poly Etch | LAM TCP9406SE | | | CoSi/Poly Etch | CoSi/Poly Etch |
| | PR Strip | YES or Gasonics | Dry-EKC | | PRS trip | PR Strip |
| ReOx | Oxidation | Tylan Tytan AP | Dry SiO2 | 11 nm | Oxidation | Oxidation |
| N-LDD | N-LDD Photo | PAS5500/60, PAS2500/40 | N + mask | | Masked | Masked |
| | N-LDD Implant | Varian EHPi500 | As implant | | Masked | Masked |
| | PR Strip | YES or Gasonics | Dry-SPM | | PR Strip | PR Strip |
| P-LDD | P-LDD Photo | PAS5500/60, PAS2500/40 | P + mask | | Masked | Masked |
| | P-LDD Implant | Varian EHPi500 | BF2 implant | | Masked | Masked |
| | PR Strip | YES or Gasonics | Dry-SPM | | PR Strip | PR Strip |
| LDD Spacer | Oxide Deposition | Novellus Concept1 | | 200 nm | Oxide Deposition | Oxide Deposition |
| | LDD Etch | LAM 4526i Rainbow | | | LDD Etch | LDD Etch |
| N+ | N + Photo | PAS5500/60, PAS2500/40 | N + mask | | Masked | Masked |
| | N + Implant | Varian VIISion 80 | As implant | | Masked | Masked |
| | PR Strip | Gasonics | Dry-SPM | | PRS trip | PR Strip |
| P+ | P + Photo | PAS5500/60, PAS2500/40 | P + mask | | Masked | Masked |
| | P + Implant | Varian VIISion 80 | BF2 implant | | Masked | Masked |
| | PR Strip | Gasonics | Dry-SPM | | PR Strip | PR Strip |

Other than that, the CMOS processing of Table 4 is but one of any number of standard CMOS processes known to those skilled in the art and that could be used to form the CMOS devices in the silicon islands 604, and consequently need not be described further herein.

This completes the CMOS device formation part 106 of the process 100. The end result includes complete CMOS devices in the silicon thin film islands 604, missing only the usual interconnect layers. As will be apparent to those skilled in the art, while the schematic representation of the Figures shows only a single silicon island 604 with a single CMOS device and associated gate stack, in any practical embodiment there may be many CMOS devices and those devices may be formed in many silicon islands 604, depending on application requirements.

### Acoustic Wave Device Formation

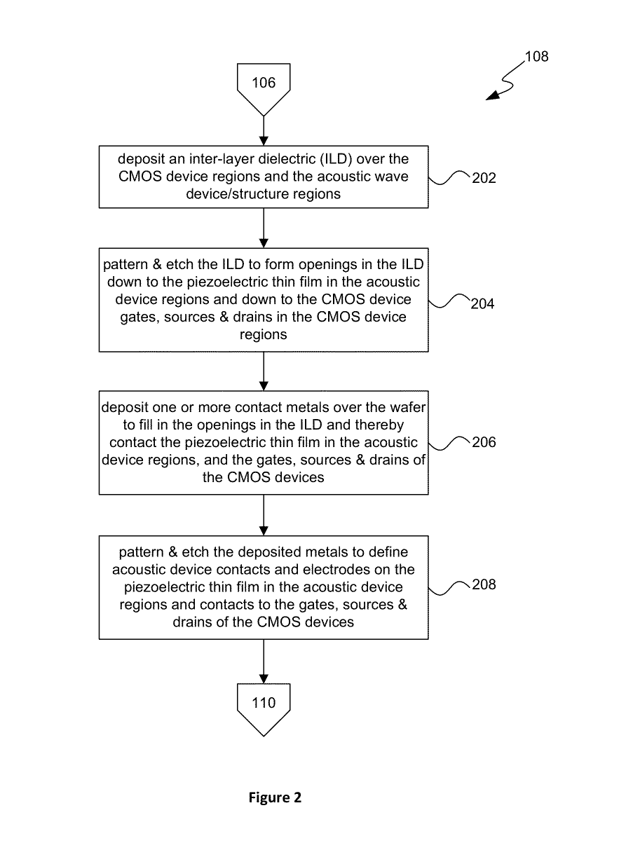

Once the CMOS devices have been formed at step 106, the CMOS device interconnects and, if the device includes any bulk acoustic wave (BAW) structures, the bulk acoustic wave structure electrodes and contacts are then formed. First, these contacts and electrodes are formed on the CMOS device (upper) side of the piezoelectric thin film 404 using a first contact process 108, as shown in the flow diagram of FIG. 2.

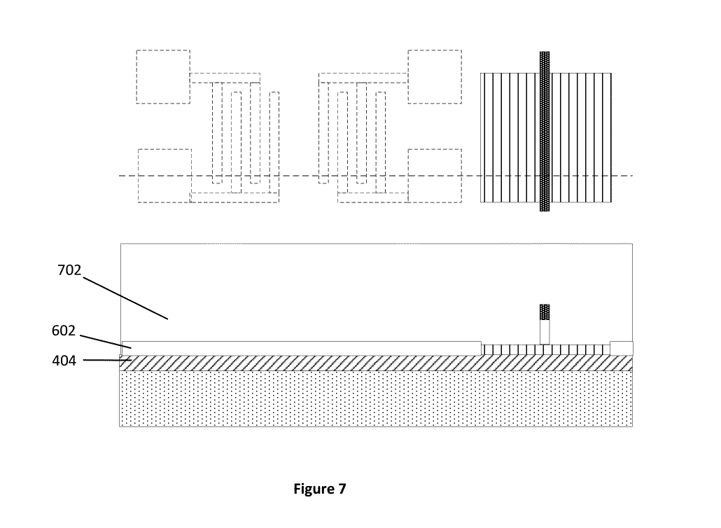

As known by those skilled in the art, in essentially any standard CMOS device process, interconnect layers are formed over the CMOS devices by alternately depositing patterned metal and inter-layer dielectric (ILD) layers. In the described embodiment, a single ILD layer 702 is formed by depositing, at step 202, a thick (e.g., ˜1 μm) multi-layer PECVD BPSG (plasma-enhanced chemical vapor deposition boro-phospho-silicate glass) over the entire wafer and then densifying the deposited layer, to form the general structure illustrated in FIG. 7. Thus the ILD layer 702 is formed on the protective field oxide layer 602 in the acoustic wave device/structure regions 504, and on the un-metallised CMOS devices in the CMOS device regions 502. In other embodiments, multiple alternating ILD and metal layers may be deposited.

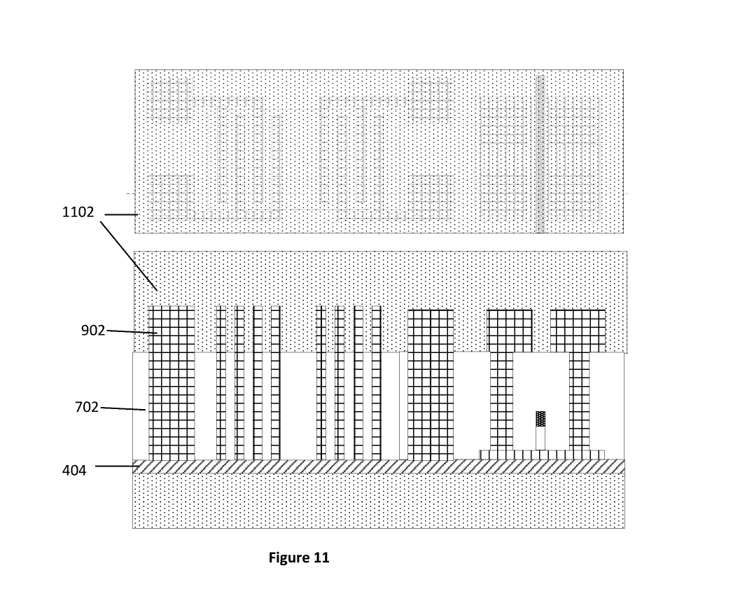

As also shown in the plan view of the upper part of FIG. 7, the gate voltage to each CMOS transistor is provided from an (as yet unmetallised) gate contact 704 laterally spaced from the CMOS transistor body and via a corresponding elongate gate electrode/stack 706 which is also visible in the cross-sectional side view in the lower part of the Figure. For convenience, the gate contact 704 is omitted from the other plan view Figures (except for FIG. 11), but should be understood as being present.

TABLE 5

| Step | Operation | Tool | Condition | Target | BAW | SAW |
|---|---|---|---|---|---|---|
| Contact ILD | NSG Deposition | Novellus Concept1 | | 200 nm | NSG Deposition | NSG Deposition |
| | BPSG Deposition | Novellus Concept1 | | 900 nm | BPSG Deposition | BPSG Deposition |
| | BPSG Dens | Tylan Tytan AP | N2 anneal | | BPSG Dens | BPSG Dens |

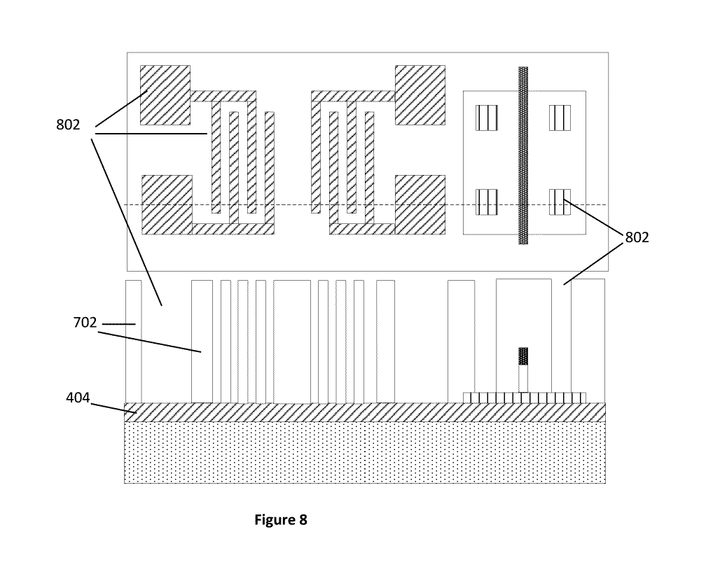

At step 204, a contact photoresist mask is used to selectively etch regions of the ILD layer 702 and the underlying field oxide layer 602, as shown in Table 6 below, to completely remove the IDL layer 702 from those regions, as shown in FIG. 8. The resulting openings 802 extend right down to form contacts to each electronic device on the wafer, including any resistors and capacitors in addition to the source, drain, and gate contact of each MOS transistor in the CMOS device regions 504 to allow one or more contact metals to be deposited in those openings 802. If the device includes any bulk acoustic wave (BAW) structures, then the openings 802 also extend down to the piezoelectric layer 404 in the acoustic wave device/structure regions 502, as shown, to define one or more backplane electrodes of the bulk acoustic wave structures. Each BAW structure can be in the form of a set of interdigitated finger electrodes (IDT), as shown, or alternatively as a single plate deposited on and parallel to the piezoelectric layer 404. Otherwise, if the acoustic wave structures device are all SAW structures, then there are no openings 802 formed in the acoustic wave structure regions 502.

TABLE 6

| Step | Operation | Tool | Condition | Target | BAW | SAW |
|---|---|---|---|---|---|---|
| Contact | Contact Photo | PAS5500/60 | | | Contact Photo | Masked |
| | Contact Etch | LAM 4526i Rainbow | | | Contact Etch | Masked |
| | PR Strip | YES or Gasonics | Dry-SPM | | PR Strip | PR Strip |

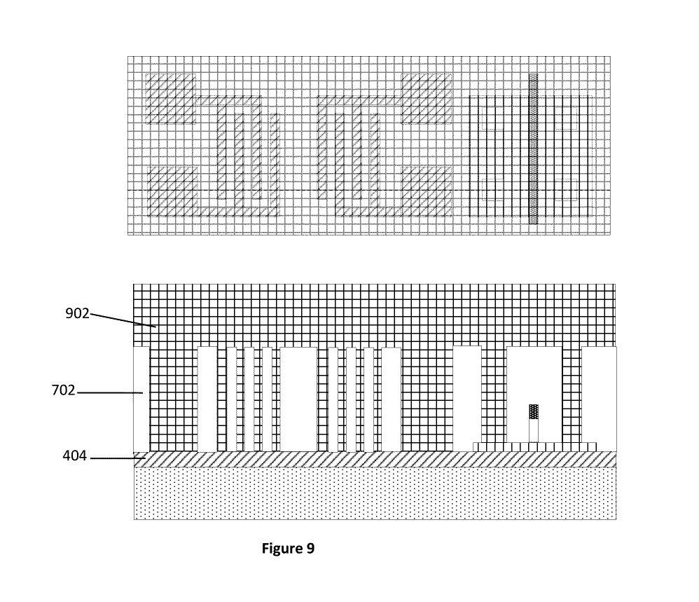

At step 206, one or more contact metals 902 are deposited over the wafer (e.g., ˜1 μm total thickness of metal) using a process such as that shown in Table 7 below, to not only completely fill the openings 802 in the ILD layer 702, but also to form a overlying planar layer over the densified ILD layer 702, as shown in FIG. 9. Only a single metal layer 902 is shown in FIG. 9 for simplicity, but in practice up to three metal layers are typically deposited. In any case, the metal layers 902 contact the piezoelectric layer 404 in the bulk acoustic wave device/structure regions 504, and contact the gate stacks, sources, and drains of the MOS transistor structures in the CMOS device regions 502.

TABLE 7

| Step | Operation | Tool | Condition | Target | BAW | SAW |
|---|---|---|---|---|---|---|
| Metal-1 | Metal Sputter | AMAT Endura5500 | | 960 nm | Metal Sputter | Metal Sputter |

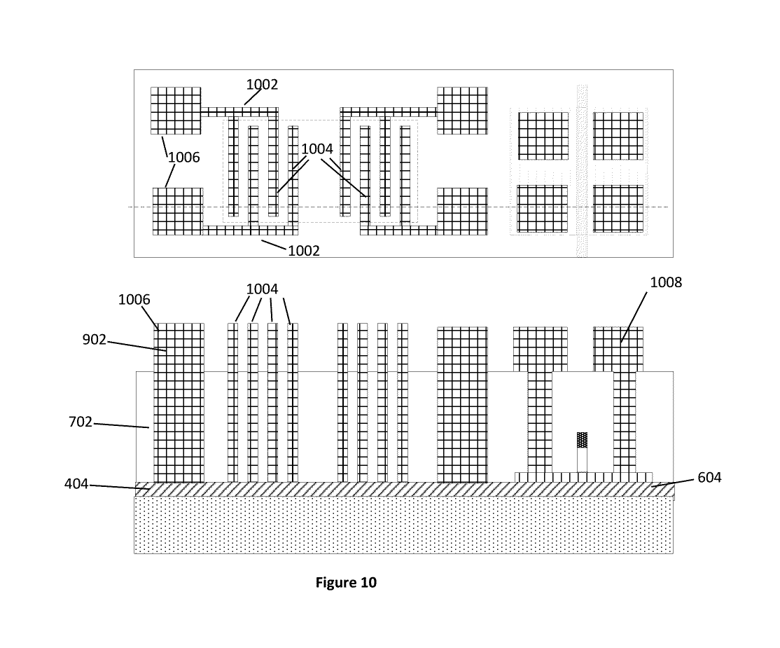

At step 208, the deposited metal layers 902 are selectively etched (i.e., patterned) using standard lithographic and etch processes such as those shown in Table 8 below, to produce the structure shown in FIG. 10. In this embodiment, the metal etch mask is configured so that, except for the elongate conductors 1002 interconnecting the acoustic wave transducer electrodes 1004 and the acoustic wave device contact pads 1006, the portions of the metal layers that were above the remaining ILD 702 in the bulk acoustic wave device/structure regions 504 are etched away completely, leaving only those parts of the metal layer 902 that filled the openings 802 in the metal layer 702 standing above the ILD layer 702. In contrast, in the CMOS device regions 502, the remaining metal contact regions 1008 are wider than the corresponding openings in the ILD layer 702 so that these metal regions 1008 have shoulder portions in contact with corresponding portions of the upper surface of the ILD layer 702. This arrangement provides a relatively large contact area to the smaller gate, source, and drain regions of the MOS transistors.

TABLE 8

| Step | Operation | Tool | Condition | Target | BAW | SAW |
|---|---|---|---|---|---|---|
| | Metal-1 Photo | PAS5500/60 | | | Metal-1 Photo | |
| | Metal-1 Etch/PR Strip | LAM TCP9600CFE | | | Metal-1 Etch/PR Strip | Metal-1 Etch/PR Strip |
| Sinter | Sinter | Tylan Tytan AP | | | Sinter | Sinter |

Returning to FIG. 1, at step 110, one or more passivation layers 1102 are deposited over the patterned metal layer 902 and the patterned ILD layer 702, using a process such as that shown in Table 20 below, resulting in the structure shown in FIG. 11.

TABLE 9

| Step | Operation | Tool | Condition | Target | | BAW | SAW |
|---|---|---|---|---|---|---|---|
| Silox | PSG Deposition | Novellus Concept1 | | 500 | nm | PSG Deposition | PSG Deposition |
| | Undoped Deposition | Novellus Concept1 | | 700 | nm | Undoped Deposition | Undoped Deposition |
| Planarise | CMP | Axus | Planarise and Polish | <1 | nm (rms) | CMP | CMP |
| | Clean | | | | | Clean | Clean |
| | Activation | | | | | Activation | Activation |
| Wafer Bond | Bond Handle Wafer | EVG Gemini | | | | Bond Handle Wafer | Bond Handle Wafer |
| Wafer De-bond | Remove substrate | | | | | Remove substrate | Remove substrate |
| | Clean | | | | | Clean | Clean |
| Pad Opening | Pad Photo | PAS5500/60 | | | | Pad Photo | Pad Photo |
| | Pad Etch | Wet etch | | | | Pad Etch | Pad Etch |
| | PR Strip | YES or Gasonics | Dry-SPM | | | PR Strip | PR Strip |
| Metal | Metal Sputter | AMAT Endura5500 | | 730 | nm | Metal Sputter | Metal Sputter |
| SAW | SAW Photo | | | | | SAW Photo | SAW Photo |
| | Metal-1 Etch/PR Strip | LAM TCP9600CFE | | | | Metal-1 Etch/PR Strip | Metal-1 Etch/PR Strip |
| | Post Clean | | | | | Post Clean | Post Clean |
| Sinter | Sinter | Tylan Tytan AP | | | | Sinter | Sinter |

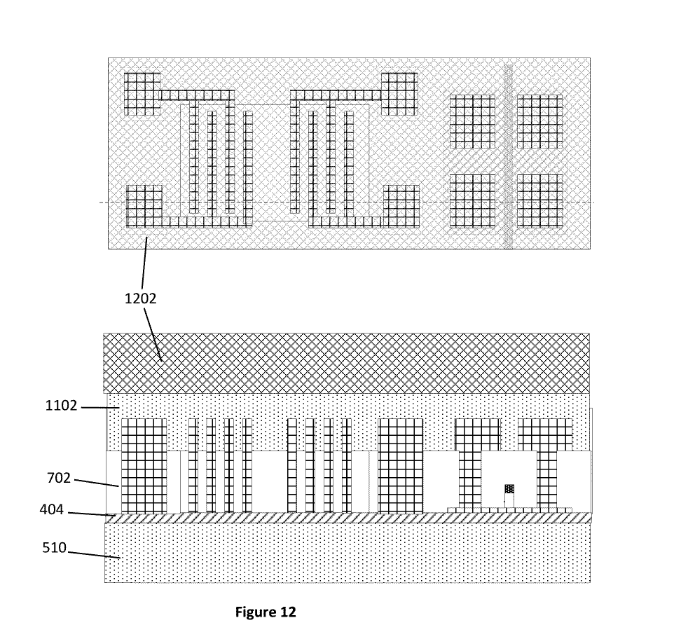

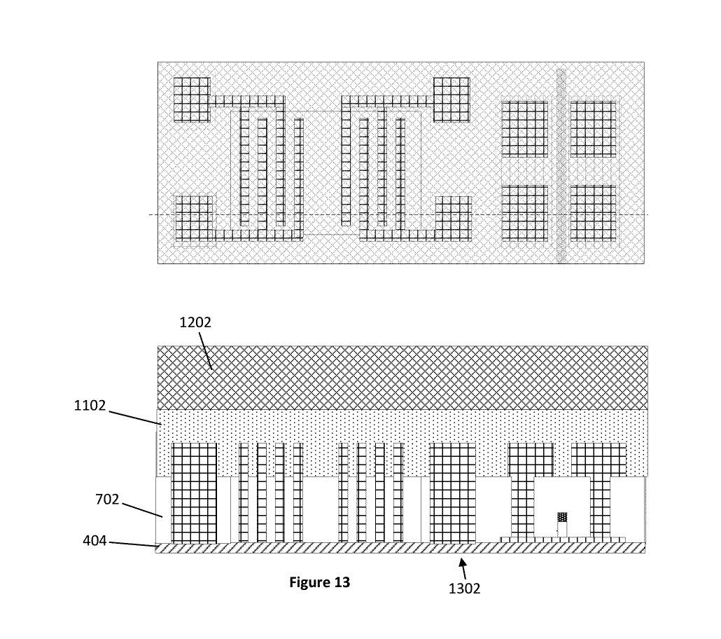

At step 112, a handle wafer or superstrate 1202 is bonded to the upper surface of the passivation layer 1102, as shown in FIG. 12. If necessary, the passivation layer 1102 can be planarised prior to the bonding step, using a standard CMP (chemical-mechanical planarisation) process, for example. At step 114, the original supporting substrate or wafer 510 is removed, thereby exposing the lower surface 1302 of the piezoelectric thin film 404, as shown in FIG. 13.

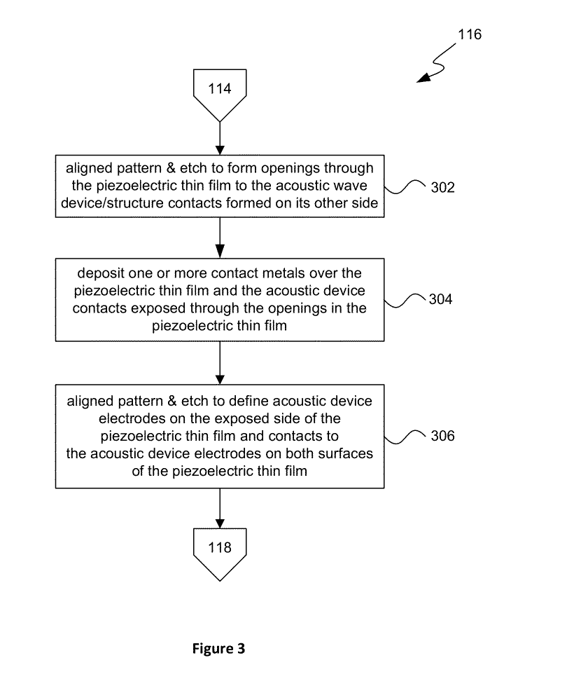

At step 116, a second contact process 116, as shown in FIG. 3, is used to form a second set of contacts/electrodes on the newly exposed lower surface 1302 of the piezoelectric layer 404. At step 302 of the second contact process 116, an aligned photolithography step is used to form a photoresist mask on the lower surface 1302 of the piezoelectric thin film 404, and the exposed regions of this piezoelectric layer 404 are then etched away completely to form openings that extend right through the piezoelectric thin film 404 to the underlying contacts to the CMOS devices and to the underlying contacts to any bulk acoustic wave device/structure contact metal regions, thereby exposing those contacts for contacting.

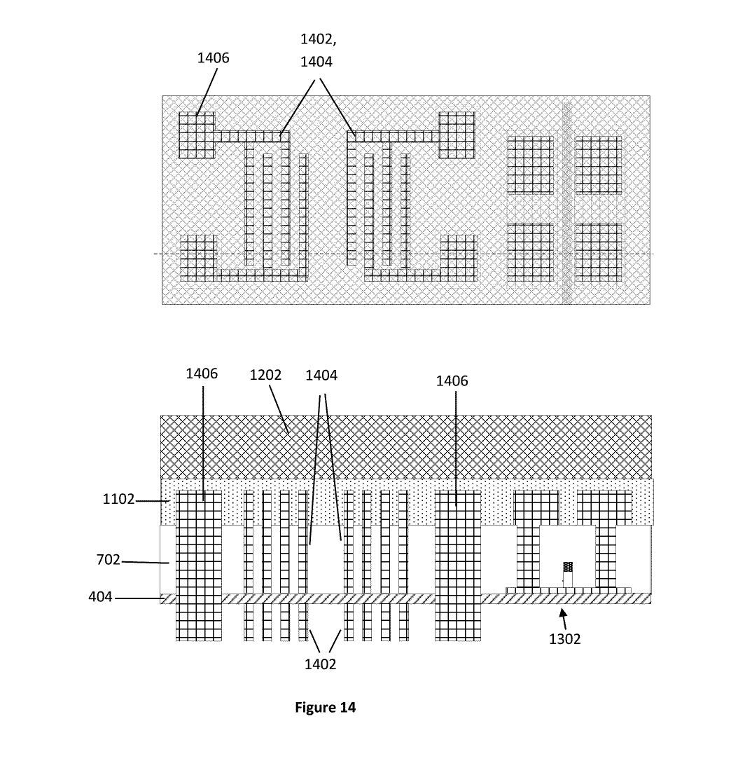

At step 304, one or more metals (e.g., aluminium, and for sensing applications, followed by an optional thin protective gold layer) are deposited over the surface 1302 of the piezoelectric thin film 404 and the contact metal regions exposed through the openings in the piezoelectric thin film 404. At step 306, a further aligned photolithography step is used to form another photoresist mask on the newly deposited metal layer to define openings aligned but complementary to the contact metal regions and any BAW electrode(s) on the other side of the piezoelectric thin film 404, and the regions of the metal layer exposed through the mask are completely removed by etching, resulting in the acoustic wave device contacts/electrode structures shown in FIG. 14.

The acoustic wave device structures shown in FIG. 14 include pairs of interdigitated finger electrodes 1402 on one side of the piezoelectric thin film 404 mutually aligned with corresponding pairs of interdigitated finger electrodes 1404 on the other side of the piezoelectric thin film 404, thus constituting bulk acoustic resonator (BAR) structures. The contacts to the electrodes structures 1402, 1404 on both sides of the piezoelectric thin film 404 are made via the shared acoustic wave structure contacts 1406 that interconnect the acoustic wave structures 1402, 1404 on either side of the piezoelectric thin film 404 by extending through that film 404. Contacts to the CMOS devices on the other side of the piezoelectric thin film 404 are formed in the same manner but are not shown in the Figures.

In general, the final processed wafer can include CMOS devices in combination with (i) SAW structures only, (ii) BAW/FBAR structures only, or both SAW structures and BAW/FBAR structures, depending on application. Typically, RF filters and/or oscillators can use either SAW structures or BAW structures. For sensing applications, BAW structures are usually used for sensing liquids, whereas SAW structures are used for sensing gases.

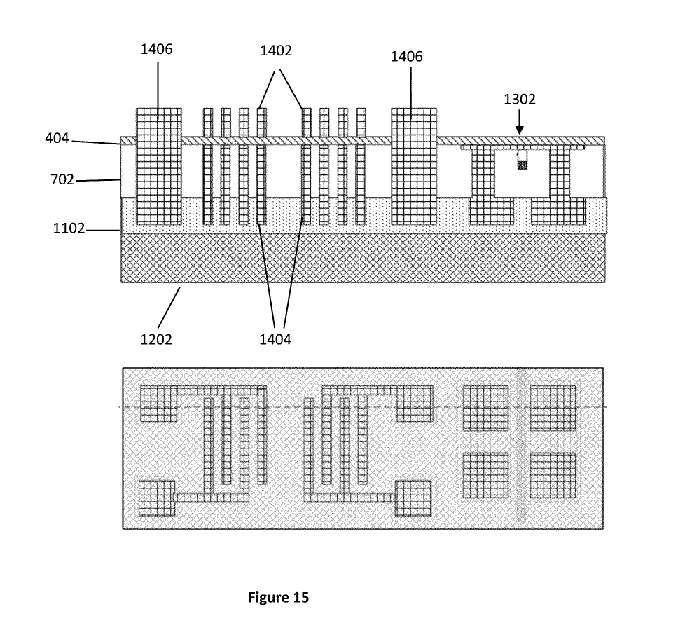

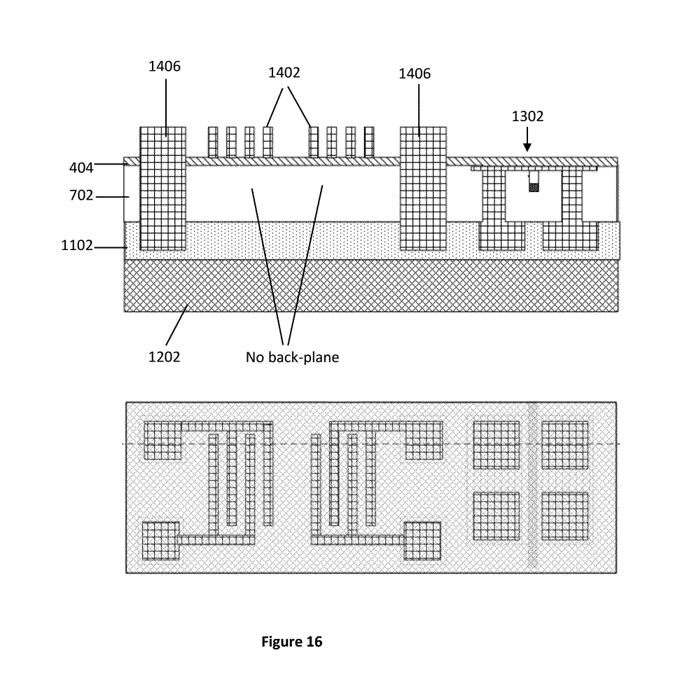

The resulting overall structure is shown schematically in FIG. 15, flipped or inverted so that the handle wafer 1202 becomes a supporting substrate for the CMOS devices and the bulk acoustic wave device/structures, as shown. By way of contrast, FIG. 16 shows the same device, but where the acoustic wave structure is a surface acoustic wave structure, rather than a bulk acoustic wave structure as shown in FIG. 15. Of course, either or both kinds of acoustic wave structures can be included in practice.

As will be apparent to those skilled in the art, the resulting inter-digitated electrodes (IDT) of the acoustic wave device/structure are aligned on both sides of the piezoelectric layer 404, and together these constitute a thin film bulk acoustic resonator (FBAR) device. There is no loading on the exposed IDT, as the only additional layer is a non-loading protective polymer (not shown). For sensing applications, the protective polymer is omitted so that the IDT is exposed for loading with substances to be sensed.

Many modifications will be apparent to those skilled in the art without departing from the scope of the present invention.

1. An integrated CMOS and acoustic wave device, including:
an electrically insulating piezoelectric thin film having opposed first and second surfaces;
one or more semiconductor-on-insulator (SOI) CMOS devices formed in a semiconductor thin film disposed on one or more portions of the first surface of the electrically insulating piezoelectric thin film; and
at least one acoustic wave structure having electrically conductive transducer electrodes disposed on at least one of the first and second surfaces of the piezoelectric thin film.

2. The device of claim 1, wherein the CMOS devices include at least one of partially depleted and fully depleted CMOS devices.

3. The device of claim 1, wherein the piezoelectric thin film provides a substantial cooling path for the CMOS devices.

4. The device of claim 3, wherein the piezoelectric thin film is substantially unsupported and the majority of the cooling through the piezoelectric thin film is along the plane of the piezoelectric thin film.

5. The device of claim 1, wherein the electrically conductive transducer electrodes are disposed on at least the second surface of the piezoelectric thin film.

6. The device of claim 1, wherein the electrically conductive transducer electrodes are disposed on the first and second surfaces of the piezoelectric thin film.

7. The device of claim 6, wherein at least some of the electrically conductive transducer electrodes on the first surface of the piezoelectric thin film are aligned with corresponding ones of the electrically conductive transducer electrodes on the second surface of the piezoelectric thin film.

8. The device of claim 1, including electrically conductive contacts that pass through the piezoelectric thin film.

9. The device of claim 1, wherein the electrically conductive transducer electrodes define interdigitated acoustic wave transducers.

10. The device of claim 1, wherein the at least one acoustic wave structure includes at least one surface acoustic wave structure.

11. The device of claim 1, wherein the at least one acoustic wave structure includes at least one bulk acoustic wave structure.

12. The device of claim 1, including a handle substrate bonded to the first side of the semiconductor thin film via one or more layers, the one or more layers including one or more interconnect layers.

13. The device of claim 1, wherein the semiconductor thin film is a silicon thin film and the piezoelectric thin film is an AlN thin film.

14. A process for producing an integrated CMOS and acoustic wave device, including:
forming or receiving a semiconductor-on-insulator (SOI) substrate having a semiconductor thin film disposed on an electrically insulating piezoelectric thin film disposed on a supporting substrate;
forming CMOS devices in one or more first portions of the semiconductor thin film; and
forming at least one acoustic wave structure having mutually spaced electrically conductive transducer electrodes disposed on at least one surface of the piezoelectric thin film, at least one dielectric material being disposed therebetween and on the at least one surface of the piezoelectric thin film.

15. The process of claim 14, wherein the piezoelectric thin film has opposed first and second surfaces, the semiconductor thin film is disposed on the first surface of the piezoelectric thin film, and the transducer electrodes are disposed on at least the second surface of the piezoelectric thin film.

16. The process of claim 15, wherein the transducer electrodes are disposed on the first and second surfaces of the piezoelectric thin film.

17. The process of claim 16, including forming electrically conductive contacts that pass through the piezoelectric thin film to interconnect the transducer electrodes across the piezoelectric thin film.

18. The process of claim 14, wherein the CMOS devices include at least one of partially depleted and fully depleted CMOS devices.

19. The process of claim 14, wherein the piezoelectric thin film provides a substantial cooling path for the CMOS devices.

20. The process of claim 19, including removing the supporting substrate to expose the piezoelectric thin film, wherein the majority of cooling through the piezoelectric thin film is along the plane of the piezoelectric thin film.

21. The process of claim 14, including:
forming one or more further layers over the CMOS devices, the one or more further layers including one or more interconnect layers;
bonding a handle superstrate to an outermost one of the one or more layers; and
removing the supporting substrate to expose the piezoelectric thin film.

22. The process of claim 14, including selectively removing one or more second portions of the semiconductor thin film to form the one or more first portions of the semiconductor thin film as mutually spaced semiconductor islands on the piezoelectric thin film.

23. The process of claim 14, wherein the semiconductor thin film is a silicon thin film and the piezoelectric thin film is an AlN thin film.
